(19) United States
(12) Patent Application Publication
(10) Pub. No.: US 2023/0136337 A1
(43) Pub. Date: May 4, 2023

(54) CIRCUIT PART AND METHOD OF MANUFACTURING CIRCUIT PART

(71) Applicants: MAXELL, LTD., Otokuni-gun, Kyoto (JP); SANKEI GIKEN KOGYO CO., LTD., Tokyo (JP)

(72) Inventors: Akiko KITO, Otokuni-gun (JP); Atsushi YUSA, Otokuni-gun (JP); Toshiyuki KITAMURA, Tokyo (JP)

(73) Assignees: MAXELL, LTD., Otokuni-gun, Kyoto (JP); SANKEI GIKEN KOGYO CO., LTD., Tokyo (JP)

(21) Appl. No.: 17/912,309

(22) PCT Filed: Mar. 31, 2021
(86) PCT No.: PCT/JP2021/013987

§ 371 Date: Sep. 16, 2022

(30) Foreign Application Priority Data
Apr. 2, 2020 (JP) 2020-066410

(51) Int. Cl. H01L 33/64; H05K 1/02; H05K 1/05

(52) U.S. Cl. CPC H01L 33/644; H05K 1/0209; H05K 1/056; H05K 2201/10106

(57) ABSTRACT

A circuit part is provided that provides both high heat dissipation and high adhesion of its circuit wiring. A circuit part includes: a metal member; an insulating resin layer located on the metal member; circuit wiring including a plating film located on the insulating resin layer; and a mounted component mounted on the circuit wiring and electrically connected to the circuit wiring, wherein a plurality of non-penetrating holes are provided in a wiring region, the non-penetrating holes being filled with the plating film, the wiring region being a portion of the resin-layer surface on which the circuit wiring is located, and the ratio of the depth d of the non-penetrating holes to the width D of the non-penetrating holes, d/D, is 0.5 to 5.

### TECHNICAL FIELD

The present invention relates to a circuit part and a method of manufacturing a circuit part.

### BACKGROUND ART

Molded interconnect devices (MIDs) have recently been commercialized in applications such as smartphones, and applications are expected to be expanded to the field of automobiles. An MID is a device composed of a resin molding with a circuit constituted by metal film on its surface, and can contribute to a reduction in the weight of the product, a reduction in thickness and a reduction in the number of parts.

MIDs with light-emitting diodes (LEDs) mounted thereon have also been proposed. When electric current flows through LEDs, they emit heat, which needs to be removed from the backside; as such, increasing the heat dissipation of an MID is important. Patent Document 1 proposes a composite part with a heat-dissipating material integrated with the MID. Further, in the MID of Patent Document 1, the circuit wiring is formed from a plating film.

### PRIOR ART DOCUMENTS

### Patent Documents

[Patent Document 1] Japanese Patent No. 3443872

### SUMMARY OF THE INVENTION

### Problems to be Solved by the Invention

In recent years, electronic devices with increasingly higher performance together with a constant reduction in size have been developed, accompanied by the development of MIDs used therein having higher density and higher functionality, which requires even higher heat dissipation. A heat dissipation material of an MID is constituted by a metal member; in an MID with a resin layer on its metal member, reducing the thickness of this resin layer is effective in improving thermal conduction from the circuit wiring on the resin layer to the metal member. However, the resin layer often contains alumina or silica particles that serve as a filler to provide thermal conduction; thus, there are limits on improving heat dissipation by only reducing the thickness of the resin layer. The present invention solves these problems by providing a circuit part (MID) providing high heat dissipation.

### Means for Solving the Problems

A first aspect of the present invention provides a circuit part including: a metal member; an insulating resin layer located on the metal member; circuit wiring including a plating film located on the insulating resin layer; and a mounted component mounted on the circuit wiring and electrically connected to the circuit wiring, wherein a plurality of non-penetrating holes are provided in a wiring region, the non-penetrating holes being filled with the plating film, the wiring region being a portion of the surface of the insulating resin layer on which the circuit wiring is located, and a ratio of a depth d of the non-penetrating holes to a width D of the non-penetrating holes, d/D, is 0.5 to 5.

A surface roughness (Ra) of a portion of the wiring region other than portions of the non-penetrating holes may be not greater than ⅕ of the depth d of the non-penetrating holes. A ratio of a distance P between adjacent ones of the non-penetrating holes to the width D of the non-penetrating holes, P/D, may be 0.3 to 3. A thickness of the circuit wiring may be larger than ½ of the depth d of the non-penetrating holes or larger than ½ of the width D. The width D of the non-penetrating holes may be 10 to 200 μm. A thickness of a portion of the insulating resin layer sandwiched between the circuit wiring and the metal member and which does not include the non-penetrating holes may be 30 to 200 μm. A distance between bottoms of the non-penetrating holes and a face of the insulating resin layer facing the metal member may be 5 to 100 μm. The non-penetrating holes may be disposed in such a sporadic manner that a density of the non-penetrating holes in the wiring region is uniform.

The insulating resin layer may include a thermosetting resin. The thermosetting resin may be epoxy resin. The insulating resin layer may include an insulating thermal-conductive filler. The circuit part may further include: an inorganic oxide layer between the metal member and the insulating resin layer. The mounted component may be positioned such that a surface thereof provided with a terminal faces the circuit wiring, and the terminal and the circuit wiring may be electrically connected by solder.

A second aspect of the present invention provides a method of manufacturing the circuit part of the first aspect, including; preparing the metal member; forming the insulating resin layer on the metal member; forming the plurality of non-penetrating holes by illuminating the wiring region of the insulating resin layer with a laser beam; forming the circuit wiring in the wiring region by electroplating; and mounting the mounted component on the circuit wiring.

### Effects of the Invention

The circuit part of the present invention provides both high heat dissipation and high adhesion of its circuit wiring.

### BRIEF DESCRIPTION OF THE DRAWINGS

FIG. 1 is a schematic top view of a circuit part of an embodiment.

FIG. 2(a) is an enlarged view of region IIA shown in FIG. 1, and FIG. 2(b) is a schematic cross-sectional view taken on line IIB-IIB of FIG. 1. In FIG. 2(a), the mounted component is not shown.

FIGS. 3(a)-(c) each show a schematic top view of a wiring region in which non-penetrating holes with an elliptically shaped opening are provided, and FIGS. 3(d), (e) each show a schematic top view of a wiring region in which non-penetrating holes with openings of various shapes are provided.

FIG. 4(a) is a schematic top view of a wiring region in which non-penetrating holes are provided at a generally uniform density, and FIG. 4(b) is a schematic top view of a wiring region in which non-penetrating holes are provided at non-uniform densities.

FIG. 5 is a flowchart illustrating a method of manufacturing a circuit part of an embodiment.

FIG. 6 shows an exemplary laser drawn pattern in an implementation where non-penetrating holes are formed by laser-beam illumination.

FIGS. 7(a)-(e) illustrate how a plating film is formed on a substrate according to an embodiment.

FIGS. 8(a)-(e) illustrate how a plating film is formed on a substrate having non-penetrating holes with a low ratio d/D.

FIG. 9 is a schematic cross-sectional view of part of a circuit part of a variation.

FIG. 10(a) is a schematic top view of a circuit part produced for Inventive Example 13, and FIG. 10(b) is a schematic cross-sectional view taken on line XB-XB of FIG. 10(a).

FIG. 11 is a photograph showing a cross section of the circuit part produced for Inventive Example 14.

### EMBODIMENTS FOR CARRYING OUT THE INVENTION

[Circuit Part]

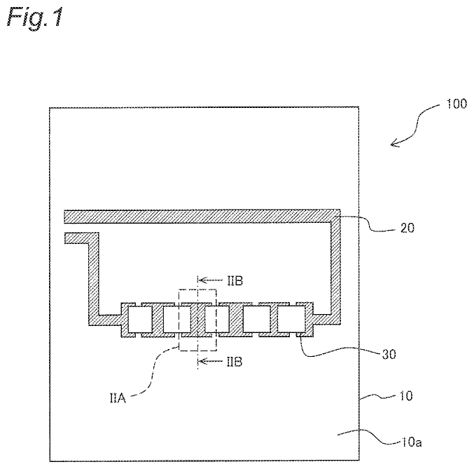

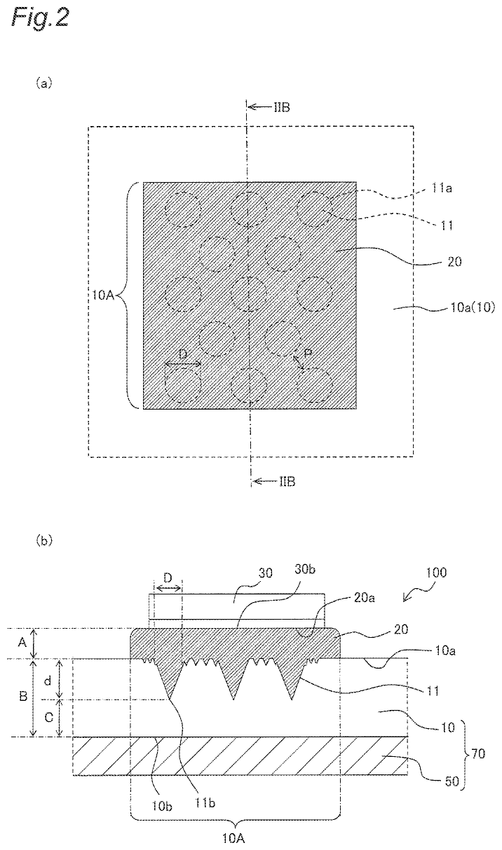

The circuit part 100 shown in FIGS. 1 and 2(a), (b) will be described. The circuit part 100 includes: a substrate 70 including a metal member 50 and an insulating resin layer 10; circuit wiring 20 including a plating film located on the insulating resin layer 10 of the substrate 70; and a mounted component 30 mounted on the insulating resin layer 10 and electrically connected to the circuit wiring 20. The mounted component 30 is positioned on the circuit wiring 20 and mounted thereon. A wiring region 10A, which is a portion of the surface 10a of the insulating resin layer 10 on which the circuit wiring 20 is located, includes a plurality of non-penetrating holes 11 (i.e., recesses) filled with plating film of the circuit wiring 20.

The metal member 50 releases heat that has been generated by the mounted component 30 mounted on the insulating resin layer 10. In view of this, the metal member 50 is preferably made of a heat-dissipating metal such as iron, copper, aluminum, titanium, magnesium, or stainless steel (SUS), for example. From the viewpoint of weight reduction, heat dissipation and costs, magnesium and aluminum are particularly preferable. One of these metals may be used alone, or two or more of them may be mixed for use. The thermal conductivity of the metal member 50 may be, for example, 80 to 300 W/m·K.

The metal member 50 is not limited to any particular shape and size, and may be designed in any manner suitable for the application of the circuit part 100. For example, the metal member 50 may be a plate-shaped body (i.e., metal plate), or take the shape of heat-dissipating fins, or may have a complex shape formed by die casting.

The insulating resin layer 10 has insulating properties to insulate the circuit wiring 20 and metal member 50 from each other to prevent a short circuit. The degree of insulation of the insulating resin layer 10 depends on the application of the circuit part 100; for example, the resistance between the circuit wiring 20 and metal member 50 during application of a voltage of 16 V is not lower than 1 MΩ. If the resistance between the circuit wiring 20 and metal member 50 is below 1 MΩ, fine current may flow from the circuit wiring 20 to the metal member 50 such that the circuit wiring 20 may not be able to function. Further, the insulating resin layer 10 has a certain degree of thermal conductivity to increase the heat dissipation of the circuit part 100. Thus, the insulating resin layer 10 is an insulating, heat-dissipating resin layer that provides both insulation and a certain degree of thermal conductivity. The thermal conductivity of the insulating resin layer 10 is 1 to 5 W/m·K, for example.

The insulating resin layer 10 includes resin. In implementations where the mounted component 30 is mounted on the insulating resin layer 10 by soldering, the resin used for the insulating resin layer 10 is preferably a heat-resistant resin with high melting point having solder-reflow resistance. The melting point of the resin used for the insulating resin layer 10 is preferably not lower than 260° C., and more preferably not lower than 290° C. This does not necessarily apply to implementations where low-temperature solder is used to mount the mounted component 30.

The resin used for the insulating resin layer 10 may be, for example, thermosetting resin, thermoplastic resin, or ultraviolet-curable resin. Particularly preferable is a thermosetting resin that can easily be formed to a thin shape, provides high forming precision, and has high heat resistance and high density after setting. Examples of thermosetting resins that can be used include heat-resistant resins such as epoxy resin, silicone resin, and polyimide resin, where epoxy resin is particularly preferable. Examples of photocuring resins that can be used include polyimide resin, epoxy resin and the like. Examples of thermoplastic resins that can be used include aromatic polyamides such as 6T nylon (GTPA), 9T nylon (9TPA), 10T nylon (10TPA), 12T nylon (12TPA), and MXD6 nylon (MXDPA), and alloy materials thereof, polyphenylene sulfide (PPS), liquid crystal polymer (LCP), polyether ether ketone (PEEK), polyetherimide (PEI), polyphenyl sulfone (PPSU), and the like. One of these thermosetting resins, ultraviolet curable resins and thermoplastic resins may be used alone, or two or more of them may be mixed and used.

The insulating resin layer 10 may include an insulating thermal-conductive filler. An insulating thermal-conductive filler can improve thermal conductivity while maintaining the insulating properties of the insulating resin layer 10. As used herein, insulating thermal-conductive filler means a filler with a thermal conductivity not lower than 1 W/m·K, and excludes electrically conductive heat-dissipating materials such as carbon. Examples of insulating thermal-conductive fillers include ceramic powders such as aluminum oxide, silicon oxide, magnesium oxide, magnesium hydroxide, boron nitride, and aluminum nitride, which are inorganic powders having high thermal conductivity. To increase the ratio of contact between filler particles to increase thermal transfer, a filler with rod-shaped particles, such as wallastonite, and/or a filler with plate-shaped particles, such as talc or boron nitride, may be mixed. One of these insulating thermal-conductive fillers may be used alone, or two or more of them may be mixed and used.

The maximum particle diameter of the insulating thermal-conductive filler (i.e., maximum particle size) is preferably 30 μm to 100 μm, for example, in implementations where relatively inexpensive ceramic particles are used. Further, in implementations where the insulating resin layer 10 has a small thickness, the maximum particle diameter of the insulating thermal-conductive filler is preferably 10 μm to 60 μm.

The insulating thermal-conductive filler is to be contained in the insulating resin layer 10 in 10 wt. % to 90 wt. %, for example, and preferably in 30 wt. % to 80 wt. %. The circuit part 100 provides sufficient heat dissipation if the amount of the insulating heat-conductive filler is in such a range.

The insulating resin layer 10 may further include a filler with rod-shaped or needle-shaped particles, such as glass fiber and/or calcium titanate, to control its strength. Further, the insulating resin layer 10 may include various general-purpose additives that are added to resin moldings, as necessary. A material containing all of the materials constituting the insulating resin layer 10, such as the resin, the insulating thermal-conductive filler and the like will be hereinafter sometimes referred to as “resin material”.

As shown in FIGS. 2(a), (b), a plurality of non-penetrating holes (i.e., recesses) 11 are provided in a wiring region 10A, which is a portion of the surface 10a of the insulating resin layer 10 on which the circuit wiring 20 is located, where the holes are filled with plating film of the circuit wiring 20. The ratio of the depth d of the non-penetrating holes 11 to the width D of the non-penetrating holes 11, d/D, is to be 0.5 to 5. The ratio d/D may preferably be 0.8 to 3.0 μm, or 1.0 to 1.6 μm. If the non-penetrating holes 11 with a ratio d/D within such a range are filled with plating film of the circuit wiring 20, this improves the adhesion of the circuit wiring 20 to the insulating resin layer 10. Further, at the non-penetrating holes 11 with a ratio d/D within such a range, the distance between the plating film of the circuit wiring 20 and the metal member 50 is reduced such that heat generated by the circuit wiring 20 and the mounted component 30 positioned thereon can easily be released to the metal member 50. This improves the heat dissipation of the circuit part 100. Thus, providing non-penetrating holes (i.e., recesses) 11 with a ratio d/D within such a range as specified above improves the heat dissipation of the circuit part 100 and the adhesion of the circuit wiring 20. Further, the circuit wiring 20 provided on the wiring region 10A including non-penetrating holes 11 with a ratio d/D within such a range has a surface 20a that provides sufficient flatness (or smoothness).

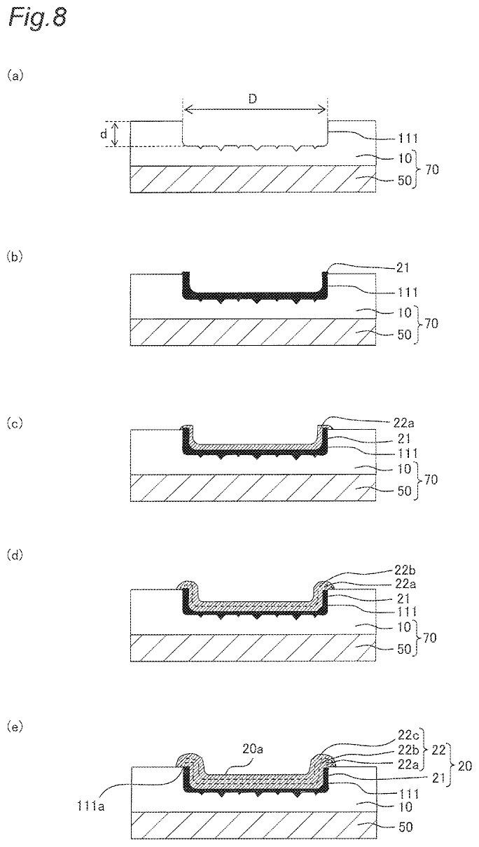

On the other hand, if the ratio d/D is outside such a range, it is impossible to provide both heat dissipation of the circuit part 100 and adhesion of the circuit wiring 20, as discussed further below. Further, sufficient flatness (or smoothness) of the circuit wiring 20 cannot be obtained. If the ratio d/D is below the lower limit for such a range as specified above, the depth d is small relative to the width D (which means shallow holes), which fails to provide sufficient adhesion of the circuit wiring 20, potentially decreasing the heat dissipation of the circuit part 100. Further, since the width D is large relative to the depth d, it is difficult to fill the non-penetrating holes 11 with plating film, potentially decreasing the flatness of the circuit wiring 20 (see FIGS. 8(a)-(e), discussed further below). Conversely, if the ratio d/D is to exceed the upper limit for such a range, the depth d must be increased (which means deeper holes). However, if d is not smaller than the thickness of the insulating resin layer 10, the circuit wiring 20 may contact the metal member 50 such that the circuit wiring 20 and metal member 50 cannot be insulated from each other. If the thickness of the insulating resin layer 10 is increased to enable increasing the depth d (which means deeper holes), this achieves insulation of the circuit wiring 20 and metal member 50 from each other, but impairs heat transfer from the circuit wiring 20 to the metal member 50 and thus reduces heat dissipation.

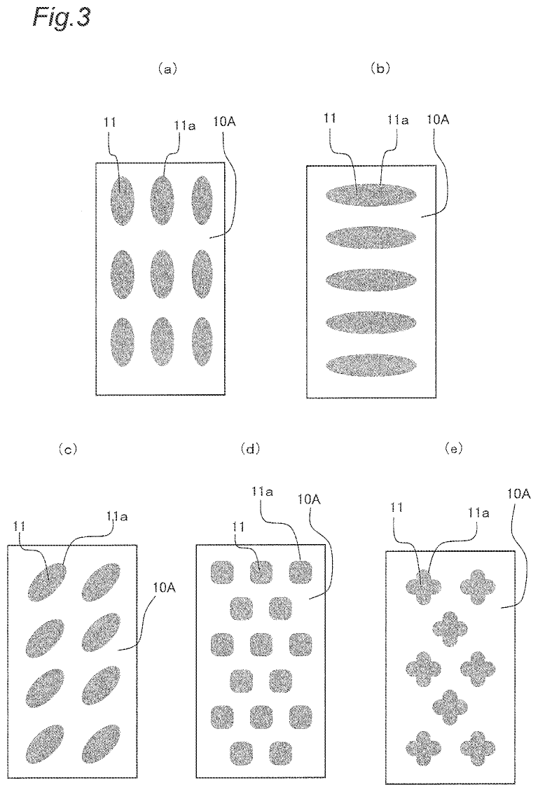

As used herein, width D of the non-penetrating holes 11, in implementations where the opening 11a of a non-penetrating hole 11 in the surface 10a (i.e., wiring region 10A) takes the shape of a perfect circle, means the diameter of this circle. Although not limiting, the shape of the opening 11a of a non-penetrating hole 11 is preferably circular to improve the smoothness and adhesion of the plating film constituting the contact wiring 20. For example, the opening may be elliptical as shown in FIGS. 3(a)-(c), or may be shaped as shown in FIGS. 3(d), (e). If the shape of an opening 11a is not perfectly circular, the width D means the diameter of a perfect circle with the same area as that of the opening 11a. Further, the depth d of a non-penetrating hole 11 is the depth of the deepest portion of the non-penetrating hole 11 (i.e., bottom lib), that is, the distance (i.e., length) between the surface 10a and the bottom lib of the non-penetrating hole 11.

The width D of a non-penetrating hole 11 is not limited to any particular value as long as the ratio d/D satisfies such a range as specified above; for example, it may be 10 to 200 μm, 20 to 150 μm, or 30 to 50 μm. If the width D is below the lower limit for such a range, sufficient adhesion of the circuit wiring 20 may not be obtained. If the width D exceeds the upper limit for such a range, it may be difficult to contain the ratio d/D within such an appropriate range as specified above.

The depth d of a non-penetrating hole 11 is not limited to any particular value as long as the ratio d/D satisfies such a range as specified above; for example, it may be 20 to 200 μm, 30 to 150 μm, or 50 to 100 μm. If the depth d is below the lower limit for such a range, sufficient adhesion of the circuit wiring 20 may not be obtained. If the depth d exceeds the upper limit for such a range, the circuit wiring 20 and metal member 50 may not be sufficiently insulated from each other, or an increase in the thickness of the insulating resin layer 10 intended to obtain insulation may decrease heat dissipation.

The ratio of the distance P between adjacent ones of the non-penetrating holes 11 to the width D of the non-penetrating holes 11, P/D, is preferably 0.3 to 3, 0.5 to 2.5 or 1.0 to 1.5. As used herein, distance P for the non-penetrating holes 11 means the smallest distance between one non-penetrating hole 11 and another, adjacent non-penetrating hole 11 in the surface 10a of the insulating resin layer 10 (i.e., wiring region 10A), and is the smallest distance from the edge of the opening 11a of one non-penetrating hole 11 to the edge of the opening 11a of another, adjacent non-penetrating hole 11. If the ratio P/D is below the lower limit for such a range as specified above, the non-penetrating holes 11, separated by the distance P, are too close to each other, potentially leading to insufficient flatness of the circuit wiring 20 formed thereon. If the ratio P/D exceeds the upper limit for such a range, the distance P for the non-penetrating holes 11 is too large, reducing the number of non-penetrating holes 11 that can be provided, potentially leading to insufficient heat dissipation of the circuit part 100 and insufficient adhesion of the circuit wiring 20.

The distance P for the non-penetrating holes 11 is not limited to any particular value as long as the ratio P/D satisfies such a range, and may be 20 to 300 μm or 50 to 150 μm, for example.

The depth d and width D of a non-penetrating hole 11, as well as the distance P for the non-penetrating holes 11, can be calculated by averaging those for the non-penetrating holes 11 present in a predetermined region (i.e., measured region) for example. For example, the calculation may be done by measuring heights in the wiring region 10A by optical measurement in the following manner: First, the circuit wiring 20 is peeled away from the insulating resin layer 10 to expose the wiring region 10A. Optical measurement equipment such as a laser microscope is used to measure the surface roughness (Ra) of an entire predetermined sub-region (i.e., measured region) of the wiring region 10A. A portion of the measured region that has a depth not smaller than twice the surface roughness (Ra) of the entire measured region is determined to be a non-penetrating hole (i.e., recess) 11; the width D of each individual non-penetrating hole 11 and the distance P between adjacent ones of the non-penetrating holes 11 are measured; and the average is calculated. In determining the depth d of the non-penetrating holes 11, to eliminate noise due to optical measurement, it is preferable to take the variations in the depth d into consideration by measuring ten or more non-penetrating holes 11 and calculating the average.

Further, the depth d and width D of a non-penetrating hole 11 as well as the distance P for the non-penetrating holes 11 may be calculated by shape analysis using X-ray CT in the following manner: For example, if the metal member 50 is formed from aluminum and the circuit wiring 20 is formed from copper, a portion of the circuit part 100 of a predetermined size that includes part of the circuit wiring 20 is cut out and is measured using X-ray CT. This provides an X-ray CT image of only the circuit wiring 20 which contains copper, which has a lower X-ray permeability than aluminum. Such an X-ray CT image is taken for each of several planes arranged in the depth direction to produce extracted slice data; the depth of the first slice to fail to show the circuit wiring 20 is treated as the depth d of the non-penetrating holes 11; and the values of the width D and distance P for the non-penetrating holes 11 are measured based on the shapes in the slice image for the surface 10a of the insulating resin layer 10. The values of the depth d, width D and distance P for individual non-penetrating holes 11 thus obtained are averaged. From the viewpoint of easy sampling and detection sensitivity, the shape analysis by X-ray CT is preferably done by cutting out an area of the wiring part of 3 to 15 mm² for measurement.

Alternatively, the depth d and width D of the non-penetrating holes 11 may be determined by cross-sectional observation of the circuit wiring 20 of the circuit part 100. The cross-sectional observation must be done based on a cross section that allows the depth d and width D of the non-penetrating holes 11 to be measured as shown in FIG. 2(b), for example, in the following manner: First, the circuit part 100 may be cut and the cut surface of a non-penetrating hole 11 is observed. Thereafter, the cut surface is polished and ground with sand paper, for example, by 2 to 3 μm, and the cut surface is observed once again. This is repeated until a photograph is obtained of a cut surface at a position where the largest depth of the non-penetrating hole 11 is observed, and the depth of the non-penetrating hole 11 determined therefrom is treated as the depth d. If a non-penetrating hole takes the shape of a circular cone as shown in FIG. 2(b), the width D can also be calculated from the photograph of the same cut surface that enables calculation of the depth d. It is preferable to take the variations of the depth d and width D into consideration by measuring ten or more non-penetrating holes 11 in the same manner and calculating the average.

The non-penetrating holes 11 are not limited to any particular construction, and can take any shape. As shown in FIGS. 2(a), (b), a non-penetrating hole 11 of an embodiment takes the shape of a circular cone with its bottom located at the surface 10a (i.e., wiring region 10A). As such, the opening 11a of a non-penetrating hole 11 takes the shape of a perfect circle. However, the non-penetrating holes 11 are not limited to this shape, and each hole may take the shape of, for example, a polygonal pyramid such as a triangular pyramid or a quadrangular pyramid, or a pyramid with a complex-shaped bottom. Alternatively, each hole may take the shape of a circular column, a rectangular polygonal prism, or a prism with a complex-shaped bottom, or a hemisphere. From the viewpoint of easiness of forming the non-penetrating holes 11 (i.e., ease of work), it is preferable that the interior of each non-penetrating hole 11 does not expand relative to the opening 11a. That is, the area of a cross section of the interior of a non-penetrating hole 11 that is parallel to the surface 10a is preferably not larger than the area of the opening 11a. In view of this, if a non-penetrating hole 11 takes the shape of a cone or pyramid, column or prism, or hemisphere, it is preferable that the bottom thereof is positioned at the surface 10a (i.e., wiring region 10A).

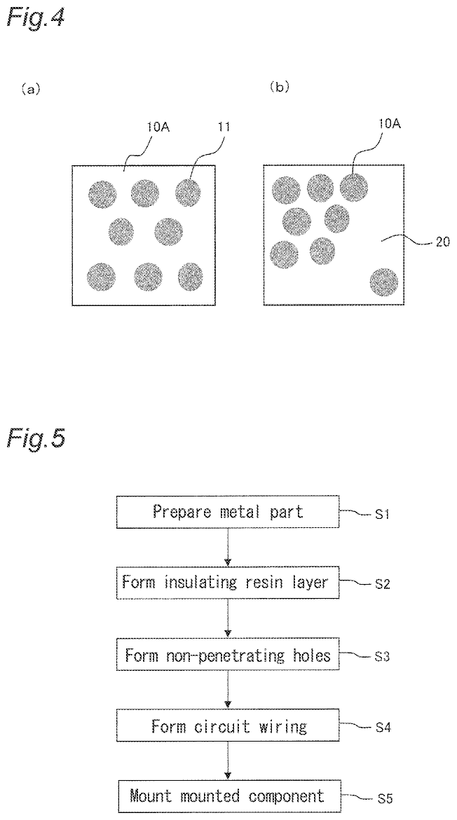

The non-penetrating holes 11 are provided in the wiring region 10A. Further, it is preferable that the non-penetrating holes 11 are only provided in the wiring region 10A and no non-penetrating holes are present in the portions of the surface 10a excluding the wiring region 10A. This reduces the time required to form the non-penetrating holes 11 (i.e., processing time), thereby improving the efficiency with which the circuit part 100 is manufactured. Further, it is preferable that the non-penetrating holes 11 are disposed in such a sporadic manner that the density of the holes in the wiring region 10A is generally uniform. This results in uniformed heat dissipation of the circuit part 100 and uniformed adhesion of the circuit wiring 20. For example, the density of the non-penetrating holes 11 in the entire wiring region 10A shown in FIG. 4(a) is the same as that in FIG. 4(b). However, the non-penetrating holes 11 shown in FIG. 4(a) are disposed in such a sporadic manner that the density in the wiring region 10A is generally uniform, while the non-penetrating holes 11 shown in FIG. 4(b) are distributed unevenly in terms of density. In FIG. 4(b), the top-left portion has a higher density of non-penetrating holes 11, while the bottom-right portion has a lower density of non-penetrating holes 11. Uniform plating film of the circuit wiring 20 grows on the wiring region 10A shown in FIG. 4(a). On the other hand, plating film does not easily grow on the bottom-right portion of the wiring region 10A shown in FIG. 4(b). Thus, the plating film on the wiring region 10A shown in FIG. 4(b) is non-uniform, decreasing the smoothness of the plating film.

Further, to form non-penetrating holes 11 in such a sporadic manner that the density in the wiring region 10A is generally uniform, it is preferable to satisfy the following conditions: It is preferable that, in the wiring region 10A, the difference between the largest value and the smallest value of the distance P (i.e., smallest distance from the edge of the opening 11a of one non-penetrating hole 11 to the edge of the opening 11a of another, adjacent non-penetrating hole 11) is smaller than 50% of the average distance P in the wiring region 10A. Further, it is preferable that the difference between the density (number of holes/mm²) in that sub-region of the wiring region 10A which has the highest density of non-penetrating holes 11 and the density (number of holes/mm²) in that sub-region which has the lowest density is smaller than 50% of the average density (number of holes/mm²) of non-penetrating holes 11 in the wiring region 10A.

The insulating resin layer 10 is not limited to any particular thickness, and may be designed in any manner suitable for the application of the circuit part 100. The thickness of the insulating resin layer 10 may be generally constant, or may vary depending on location. There is a tendency that the smaller the thickness of the insulating resin layer 10, the better the heat dissipation of the circuit part 100; in view of this, it is preferable to minimize the thickness of portions of the insulating resin layer 10 near the highly heat-generating mounted component 30. On the other hand, if the thickness of the insulating resin layer 10 is to be too small, there may be high flow resistance of resin during forming of the insulating resin layer 10, potentially causing forming defects (or filling defects). Further, it makes it difficult to form non-penetrating holes 11 with sufficient depth. In view of all this, the thickness B of portions of the insulating resin layer 11 that are sandwiched between the circuit wiring 20 and metal member 50 and include no non-penetrating holes 11 (i.e., film thickness B of the insulating resin layer 11 below the circuit wiring 20) is preferably 30 to 200 μm or 50 to 150 μm. If the thickness B varies depending on location, it is preferable that the smallest value (i.e., thickness of the thinnest portion) is within such a range.

Further, it is preferable that the thickness of portions of the insulating resin layer 10 including the non-penetrating holes 11, i.e., the distance from the bottom lib of a non-penetrating hole 11 to the face 10b of the insulating resin layer 10 that faces the metal member 50 (i.e., shortest distance), C, is 5 to 100 μm, 20 to 80 μm, or 30 to 60 μm. If the distance C is smaller than the lower limit for such a range, the circuit wiring 20 and metal member 50 may not be sufficiently insulated from each other. If the distance C is larger than the upper limit for such a range, the heat dissipation of the circuit part 100 may decrease.

The surface roughness (Ra) of the portion of the wiring region 10A other than the portions of the non-penetrating holes 11 is preferably not greater than ⅕, or not higher than 1/10, of the depth d of the non-penetrating holes 11. In the present embodiments, providing non-penetrating holes 11 improves the adhesion of the circuit wiring 20, ensuring sufficient adhesion even if the surface roughness (Ra) of the wiring region 10A is reduced. Further, since the surface roughness (Ra) of the portion of the wiring region 10A other than the portions of the non-penetrating holes 11 is reduced, this improves the flatness of the circuit wiring 20 formed thereon. On the other hand, to facilitate selectively forming plating film for the circuit wiring 20 such that it is only present in the wiring region 10A, the surface roughness (Ra) of the wiring region 10A is preferably greater than the surface roughness (Ra) of the portions of the surface 10a other than the wiring region 10A. Further, the surface roughness (Ra) of the wiring region 10A may be, for example, 1 to 30 μm, 3 to 20 μm, or 5 to 10 μm.

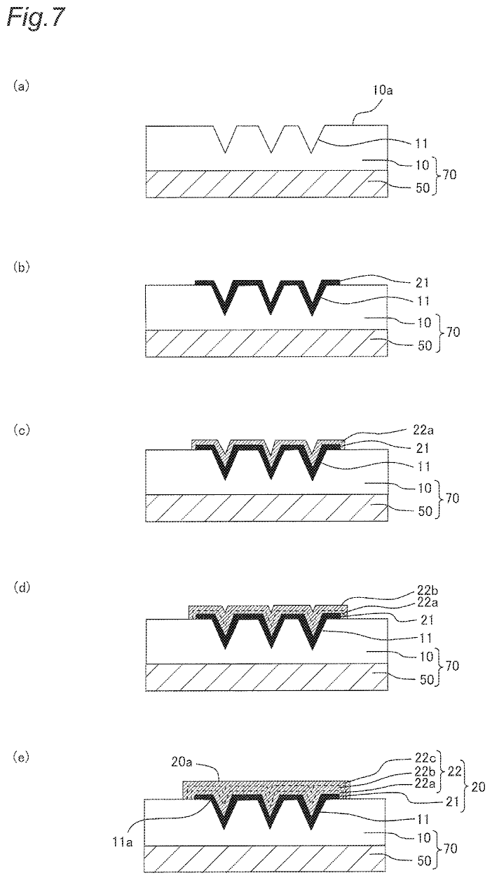

The circuit wiring 20 is formed of plating film on the wiring region 10A of the surface 10a of the insulating resin layer 10. The circuit wiring 20 is preferably composed of an electroless-plating film 21 formed on the wiring region 10A and an electroplating film 22 formed on the electroless plating film 21 (see FIG. 7(e)).

The electroless plating film 21 may be, for example, electroless nickel-phosphorus plating film, electroless copper plating film, or electroless nickel plating film, where electroless nickel-phosphorus plating is preferable. The electroplating film 22 may be nickel-phosphorus electroplating film, copper electroplating film, or nickel electroplating film. To improve solder wettability on the plating film, a plating film of gold, silver, tin or the like may be formed at the outermost surface of the circuit wiring 20.

Since the plating film constituting the circuit wiring 20 fills the non-penetrating holes 11, the circuit wiring 20 can strongly adhere to the insulating resin layer 20. The thickness A of the circuit wiring 20 is preferably larger than the smaller one of ½ of the depth d of the non-penetrating holes 11 and ½ of the width D of the holes. That is, the thickness A of the circuit wiring 20 is preferably larger than ½ of the depth d of the non-penetrating holes 11 or larger than ½ of the width D of the holes. If the thickness A of the circuit wiring 20 is within such a range, this further improves the flatness of the plating film constituting the circuit wiring 20. Nevertheless, if the size of the non-penetrating holes 11 is relatively small, the non-penetrating holes 11 can be filled with plating film even if the thickness A of the circuit wiring 20 is smaller than such a range, thereby ensuring a certain flatness of the circuit wiring 20. If the size of the non-penetrating holes 11 is relatively small, there is a concern that heat dissipation may decrease; however, reducing the thickness B of the insulating resin layer 10 to position the bottoms lib of the non-penetrating holes 11 and the metal member 50 closer to each other (i.e., reducing the distance C) can ensure that the circuit part 100 provides sufficient heat dissipation.

Thickness A of the circuit wiring 20 means the thickness that does not include that of portions thereof that fill the non-penetrating holes 11. That is, the thickness A of the circuit wiring 20 is the distance from the surface 10a of the insulating resin layer 10 up to the face 20a of the circuit wiring 20 that faces the mounted component 30. The thickness A of the circuit wiring 20 may be, for example, 10 to 100 μm, or 20 to 80 μm.

As shown in FIG. 2(b), the mounted component 30 is positioned such that its face provided with a terminal (i.e., bottom surface) 30b faces the circuit wiring 20, and the terminal and circuit wiring 20 are electrically connected by solder. The soldering is not limited to any particular solder, and a general-purpose solder may be used. When electric current flows through the mounted component 30, the component generates heat and thus becomes a source of heat. Any mounted component 30 may be used; examples include LEDs (light-emitting diodes), power modules, ICs (integrated circuits), and heat resistors.

According to the present embodiments, the surface 20a of the circuit wiring 20 on which the mounted component 30 is to be mounted is flat, which increases the adhesive strength of the mounted component 30 with respect to the circuit wiring 20, thereby improving the thermal conduction from the mounted component 30 to the circuit wiring 20. This further improves the heat dissipation of the circuit part 100.

[Method of Manufacturing Circuit Part]

A method of manufacturing the circuit part 100 will be described with reference to the flow chart shown in FIG. 5. First, a metal member 50 is prepared (step S1 in FIG. 5). The metal member 50 may be, for example, a commercial metal plate (i.e., plate-shaped body) or heat-dissipating fins, or a die casting in any desired shape.

The surface of the metal member 50 on which the insulating resin layer 10 is to be formed may be roughened to increase its adhesion to the insulating resin layer 10 that is to be deposited thereon. The roughening of the surface of the metal member 50 may use chemical etching, or a nanomolding technology (NMT) as disclosed in JP 2009-6721 A and Japanese Patent No. 5681076, for example. Alternatively, laser roughening may be performed.

Next, an insulating resin layer 10 is formed on the metal member 50 (step S2 in FIG. 5). For example, the insulating resin layer 10 may be formed by insert molding (i.e., integrated molding). Specifically, the metal member 50 is first placed inside a mold, and resin material is injected to fill in the empty space in the mold. Thus, the metal member 50 and insulating resin layer 10 are molded in an integrated manner. The insert molding used may be injection molding, transfer molding or the like. Thus, the insulating resin layer 10 and metal member 50 may be constituted by an integral molding obtained by integrated molding. As used herein, integral molding means an object produced by a process of joining an insulating resin layer 10 with a metal member 50 during molding of the resin layer (typically, insert molding), rather than separately fabricating a metal member 50 and an insulating resin layer 10 and then bonding or joining them together (i.e., secondary bonding or mechanical joining).

Next, a plurality of non-penetrating holes 11 are formed in the wiring region 10A of the insulating resin layer 10 (step S3 in FIG. 5). The formation of the non-penetrating holes 11 is not limited to any particular method; for example, the surface 10a of the insulating resin layer 10 may be illuminated with a laser beam to cut the surface to form the non-penetrating holes 11 (i.e., laser machining). Laser machining can efficiently form a plurality of non-penetrating holes 11, and also allows easy adjustment of the size of the non-penetrating holes 11 (width D and depth d). At the same time as the formation of the non-penetrating holes 11, the entire wiring region 10A may be illuminated with a laser beam to roughen the wiring region 10A. Roughening the wiring region 10A makes it easier to selectively form the circuit wiring 20 (i.e., plating film) such that the wiring is present only in the wiring region 10A, and also increases the adhesion of the circuit wiring 20. However, to ensure a certain flatness of the circuit wiring 20 that is to be formed thereon, the surface roughness (Ra) of the portion of the wiring region 10A other than the portions of the non-penetrating holes 11 is preferably not greater than ⅕, or not greater than 1/10, of the depth d of the non-penetrating holes 11. The laser machining to form the non-penetrating holes 11 is not limited to any particular type of laser beam or to any particular laser machining equipment, and any appropriate beam/equipment may be chosen for use taking account of the type of the insulating resin layer 10 and/or other factors.

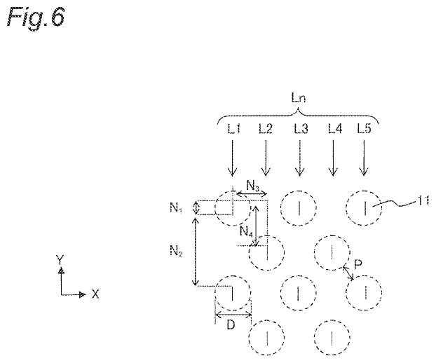

In implementations where the non-penetrating holes 11 are formed by laser machining, it is preferable, for example, to perform laser drawing in a pattern composed of discontinuous lines, as shown in FIG. 6. The laser drawing shown in FIG. 6 will be described. First, discontinuous lines L1 extending in a predetermined direction (Y-direction shown in FIG. 6) are drawn. The discontinuous lines L1 represent a pattern of line segments (laser-drawn portions), each with a length N₁, that are arranged with a distance (space) of a length N₂. Next, discontinuous lines L2 are laser-drawn where a pattern similar to that of the lines L1 is translated from the lines L1 by a distance N₃ in the direction perpendicular to the predetermined direction (i.e., X-direction shown in FIG. 6) and also translated by a distance N₄ in the Y-direction. Here, N₄=(N₁+N₂)/2. Analogous operations are repeated to draw a plurality of sets of discontinuous lines Ln extending in the Y-direction and arranged in the X-direction with an equal distance (i.e., distance N₃). This results in a laser-drawn pattern with line segments (laser-drawn portions) each with the length N₁ arranged in the X-direction with a pitch of N₁+N₂ and arranged in the Y-direction with a pitch of 2×N₃, as shown in FIG. 6. The laser beam is only directed to the line segments with the length N₁; however, since the laser beam has a width called spot diameter, it also cuts portions of the insulating resin layer 10 near the drawn pattern lines. If the line length N₁ is small, the width expansion resulting from the spot diameter is generally equal to the cut depth, creating a non-penetrating hole 11 with a cone-shaped laser-machining mark. The distance P is given by: P=√[(N₃)²+(N₄)²]−D, where D is the diameter of the non-penetrating holes 11 formed by cutting with expansion from the laser-illuminated portions with the length N₁. Patterns of non-penetrating holes 11 of various sizes can be created by changing the values of the lengths N₁ to N₄. Further, use of such laser drawing allows the non-penetrating holes 11 to be easily formed in the wiring region 10A in such a sporadic manner that the density is generally uniform. Another method of forming a plurality of non-penetrating holes 11 with a laser beam, other than forming a drawn pattern of discontinuous lines, may be illumination with a laser beam in a pulsing manner.

Next, circuit wiring 20 included in the plating film is formed on the wiring region 10A of the insulating resin layer 10. The formation of the circuit wiring 20 is not limited to any particular method, and a common method may be used. For example, in one method, a plating film is formed on the entire surface 10a, the plating film is patterned using a photoresist, and portions of the plating film other than the circuit wiring are removed by etching; in another method, the portions of the surface on which circuit wiring is to be formed are illuminated with a laser beam to roughen the resin layer, and plating film is formed only on the portions illuminated with the laser beam. Especially in implementations where the insulating resin layer 10 used is made of a thermosetting resin such as epoxy resin, roughening the wiring region 10A with a laser beam promotes adsorption of metal ions that serve as a plating catalyst, making it easier to form electroless plating film only on the wiring region 10A.

Some of the plating film constituting the circuit wiring 20 fills the non-penetrating holes 11. The formation of the circuit wiring 20 may include, as shown in FIGS. 7(a)-(e): forming an electroless plating film 21 on the wiring region 10A (see FIG. 7(a)); and forming an electroplating film 22 on the electroless plating film 21 (see FIGS. 7(b)-(e)).

The formation of the electroless plating film 21 is not limited to any particular method, and an appropriate common electroless plating method may be selected and used. Forming an electrically conductive electroless plating film 21 on the insulating resin layer 10 enables electroplating on the electroless plating film 21. Thus, the electroless plating film 21 serves as a foundation on which the electroplating film 22 can be formed.

The formation of the electroplating film 22 is not limited to any particular method, and an appropriate common electroplating method may be selected and used, where electroplating methods with high throwing power are preferable. During electroplating, large amounts of electric current flow at the corners and protrusions of the surface on which a plating film is to be formed, while smaller amounts of current flow in central portions and at recesses. The thickness of the electroplating film tends to be proportional to the strength of current; as such, if the surface on which a plating film is to be formed has protrusions and/or recesses, this produces variations in the thickness of the electroplating film. An electroplating method with high throwing power can reduce such variations in the thickness of the electroplating film. As a result, as shown in FIGS. 7(b)-(e), the electroplating films 22a, 22b and 22c formed do not have larger thicknesses at the edges of the opening 11a (i.e., corners) of a non-penetrating hole 11, but grow to a generally uniform film thickness from the inner wall of the non-penetrating hole 11 and the surface 10a. Thus, film can easily fill in the non-penetrating holes 11, and also increases the flatness of the surface of the electroplating film 23c (i.e., surface 20a of the circuit wiring 20).

As discussed above, the ratio d/D of the depth d to the width D of the non-penetrating holes 11 is 0.5 to 5. As the ratio d/D of the non-penetrating holes 11 is within such a range, the electroplating film 22 can easily fill in the non-penetrating holes 11, and also increases the flatness (or smoothness) of the surface 20a of the circuit wiring 20. On the other hand, if the ratio d/D is outside such a range, it is difficult to fill the non-penetrating holes 11 with plating film, nor can the flatness of the circuit wiring 20 be increased. For example, FIGS. 8(a)-(e) show how a plating film is formed on a substrate having a non-penetrating hole 111 with a ratio d/D smaller than 0.5, that is, a non-penetrating hole 111 with a width D that is too large relative to the height d. The electroplating films 22a, 22b and 22c, which grow from the inner wall of the non-penetrating hole 111, cannot easily fill in the non-penetrating hole 111 since the width D of the non-penetrating hole 111 is too large relative to the film thickness. It is possible to fill the non-penetrating hole 111 by forming, as shown in FIG. 8(e), a plating film with a thickness generally equal to the depth d; however, portions of the plating film located at the edges of the opening 111a of the non-penetrating hole 111 are raised, which makes it impossible to provide a flat surface 20a of the circuit wiring 20. To achieve a flat surface 20a of the circuit wiring 20, the thickness of the formed electroplating film 22 must be further increased, which would be inefficient and increase manufacturing costs.

After the circuit wiring 20 is formed on the insulating resin layer 10, a mounted component 30 is mounted on the circuit wiring 20 (step S5 in FIG. 5). This results in the circuit part 100 of the present embodiments. The mounting of the mounted component 30 is not limited to any particular method, and a common method can be used: for example, the mounted component 30 may be soldered to the insulating resin layer 10 by a solder-reflow method in which solder at room temperature and the mounted component 30 are placed on the circuit wiring 20 and then moved through a high-temperature reflow furnace, or a laser-soldering method (i.e., spot mounting) in which a laser beam is directed to the interface between the insulating resin layer 10 and mounted component 30 to solder them together.

In the circuit part 100 of the present embodiments described above, non-penetrating holes 11 with a ratio d/D within a certain range are formed in the wiring region 10A to provide both high heat dissipation and high adhesion of the circuit wiring 20 to the insulating resin layer 10. Further, the surface 20a of the circuit wiring 20 on which the mounted component 30 is to be mounted is flat, which improves the adhesive strength of the mounted component 30 to the circuit wiring 20 and improves thermal conductivity from the mounted component 30 to the circuit wiring 20. This further improves the heat dissipation of the circuit part 100.

[Variations]

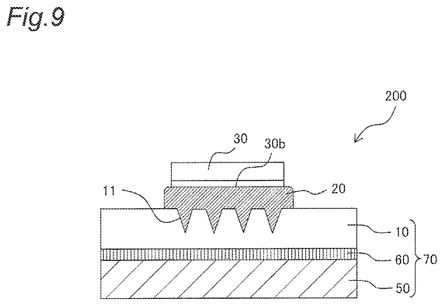

In the circuit part 100 of the embodiments described above, the insulating resin layer 10 is formed directly on top of the metal member 50; however, embodiments are not limited to such an arrangement. As shown in FIG. 9, a ceramic layer 60 may be provided between the metal member 50 and insulating resin layer 10. The present variation will be described below with reference to a circuit part 200 including the ceramic layer 60 shown in FIG. 9. The construction of the circuit part 200 is the same as that of the above-described circuit part 100 shown in FIGS. 2(a), (b) except for the presence of the ceramic layer 60. Accordingly, for the present variation, the requirements other than the ceramic layer 60 will not described.

The ceramic layer 60 is provided on the metal member 50. The ceramic layer 60 is more difficult to cut with a laser beam than the insulating resin layer 10. Thus, if non-penetrating holes 11 are formed with laser-beam illumination, the non-penetrating holes 11 are prevented from reaching the metal member 50. Further, the ceramic layer 60 provides insulation and works together with the insulating resin layer 10 to insulate the circuit wiring 20 and metal member 50 from each other to prevent a short circuit. The degree of insulation depends on the application of the circuit part 100; the resistance is preferably not lower than 5000 MΩ upon application of a voltage of 500 V, for example.

Further, the ceramic layer 60 preferably has high thermal conductivity to increase the heat dissipation of the circuit part 100. Thus, the ceramic layer 60 is preferably an insulating thermal-conductive layer (i.e., insulating heat-dissipating layer) that provides both insulation and high thermal conductivity. The thermal conductivity of the ceramic layer 60 is 5 to 150 W/m·K., for example. Further, to efficiently release heat generated by the mounted component 30 on the insulating resin layer 10 to the metal member 50, the thermal conductivity of the ceramic layer 60 is preferably lower than the thermal conductivity of the metal member 50 and higher than the thermal conductivity of the insulating resin layer 10.

Examples of the ceramics contained in the ceramic layer include aluminum oxide (alumina), aluminum nitride, boron nitride, silicon nitride, beryllium oxide, silicon carbide, yttria, zirconia, titanium dioxide, silicon dioxide, clay minerals and the like, where yttria and alumina, which can easily form a dense thin film at low cost, are preferable. One of these ceramics may be used alone, or two or more of them may be mixed and used.

The film thickness of the ceramic layer 60 may be, for example, 1 μm to 100 μm, 5 μm to 20 μm, or 5 μm to 10 μm.

A method of manufacturing the circuit part 200 of the present variation will now be described. First, a metal member 50 is prepared.

Next, a ceramic layer 60 is formed on the metal member 50. The formation of the ceramic layer 60 is not limited to any particular method; examples of methods that can be used include: physical vapor deposition (PVD) methods such as vacuum deposition or ion plating; chemical vapor deposition (CVD) methods such as plasma CVD; aerosol deposition (AD); sputtering; spraying; cold spraying; and warm spraying. In implementations where the metal member 50 is made of aluminum or alloys thereof, the ceramic layer 60 may be an “alumite” layer (i.e., coating of aluminum oxide (alumina)) formed through anodic oxidation. The alumite layer may be formed only on part of the metal member 50, or may be formed on the entire surface of the metal member 50. Furthermore, a plurality of ones of the above-described film-forming methods may be used to form a ceramic layer 60 composed of multiple layers to increase film strength.

Next, an insulating resin layer 10 is formed on the ceramic layer 60; a plurality of non-penetrating holes 11 are formed in the wiring region 10A of the insulating resin layer 10; circuit wiring 20 including plating film is formed on the wiring region 10A of the insulating resin layer 10; and a mounted component 30 is mounted on the circuit wiring 20, which results in the circuit part 200 of the present variation. The formation of the insulating resin layer 10, the formation of the plurality of non-penetrating holes 11, the formation of the circuit wiring 20, and the mounting of the mounted component 30 can be performed in the same manner as for the above-described method of manufacturing the circuit part 100.

The circuit part 200 of the present variation produces substantially the same effects as the above-described circuit part 100. Further, the circuit part 200, including the ceramic layer 60, can more reliably insulate the circuit wiring 20 and metal member 50 from each other.

### EXAMPLES

Now, the present invention will be specifically described with reference to inventive and comparative examples; however, the present invention is not limited to the inventive and comparative examples described below.

### Inventive Example 1

For the present example, a circuit part 100 as shown in FIG. 1 was produced. The mounted component 30 was constituted by an LED (light-emitting diode).

(1) Preparation of Metal Part

To provide a metal member 50, an aluminum plate (A1050 with 99% or more aluminum, 8 cm by 12 cm) was prepared.

(2) Formation of Insulating Resin Layer

Next, a general-purpose molding machine was used to perform insert molding (i.e., transfer molding), using an epoxy resin containing 75 wt. % alumina (aluminum oxide) particles with a maximum diameter of 35 μm (thermosetting resin; thermal conductivity; 1 W/m·K), to form an insulating resin layer 10. This resulted in a substrate 70 composed of an aluminum plate (i.e., metal member) 50 and an insulating resin layer 10. The size of the insulating resin layer 10 was 40 mm by 40 mm by 200 μm in thickness. The insulating resin layer 10 was formed in central portions of the metal member 50.

(3) Formation of Non-Penetrating Holes

The region of the surface 10a of the insulating resin layer 10 on which circuit wiring 20 was to be formed (i.e., wiring region 10A) was illuminated with a laser beam to process the wiring region 10A. The laser machining (i.e., laser drawing) used a three-dimensional laser marker (MD-9920A YVO₄ laser from Keyence Corporation, with 13 W).

First, the region of the surface 10a of the insulating resin layer 10 on which the circuit wiring 20 was to be formed (i.e., wiring region 10A) was illuminated with a laser beam to roughen the region. Specifically, a pattern of parallel lines arranged with a pitch of 40 μm was laser-drawn in the wiring region 10A (laser-drawing conditions; a linear velocity of 2000 mm/s, a frequency of 40 kHz and a power of 20%). The resulting surface roughness (Ra) of the wiring region 10A was 13 μm.

Next, a plurality of non-penetrating holes (i.e., recesses) 11 were formed in the wiring region 10A by laser machining. Specifically, a pattern of discontinuous lines as shown in FIG. 6 was laser drawn in the wiring region 10A (laser-drawing conditions; a linear velocity of 30 mm/s, a frequency of 50 kHz and a power of 80%), thereby forming a plurality of non-penetrating holes 11. The number of rounds of laser drawing (i.e., number of rounds of repeated laser drawing) was 1. The dimensions of the laser-drawn patterns were as follows; N₁=35 μm, N₂=365 μm, N₃=200 μm, and N₄=200 μm. The shape of the resulting non-penetrating holes 11 was that of a circular cone with its bottom positioned at the surface 10a (i.e., wiring region 10A), as shown in FIGS. 2(a), (b).

The width D and depth d of the resulting non-penetrating holes 11, as well as the distance P between adjacent ones of the non-penetrating holes 11, were measured using a laser microscope (VK-9700 laser microscope from Keyence Corporation, with an objective magnification of 20×). The depth d was calculated by calculating the depth distribution for one non-penetrating hole 11, where the largest depth values within the cumulative frequency range of below 1% were determined to be optical noise and ignored, and treating the depth value with a cumulative frequency of 1% as the depth d of this one particular non-penetrating hole. The width D was calculated by calculating the area of the opening 11a of one non-penetrating hole 11, and treating the diameter of the opening 11a when treated as being perfectly circular as the width D of this one particular non-penetrating hole 11. For every one of the non-penetrating holes 11 present in the field of view for measurement, the width D and depth d were determined in the same manner and the averages of the widths D and depths d were calculated.

For the distance P for the non-penetrating holes 11, first, the distance between the centroid of the opening 11a of one non-penetrating hole 11 and the centroid of the opening 11a of an adjacent non-penetrating hole 11 was measured. For all the non-penetrating holes 11 present in the field of view for measurement, the distance between the centroids of adjacent openings 11a was determined in the same manner, and the average of the distances for these centroids was determined. Next, the average of the widths D that had been determined was subtracted from the average of the distances for the centroids to give the distance P for the non-penetrating holes 11.

The width D (average) of the non-penetrating holes 11 thus calculated was 155 μm, the depth d (average) was 178 μm, and the distance P for the non-penetrating holes 11 was 128 μm. Thus, the ratio d/D was 1.15. The calculated values of the width D and depth d of the penetrating holes 11, the distance P for the non-penetrating holes 11, and the ratio d/D are shown in Table 4.

(4) Formation of Circuit Wiring

(a) Application of Electroless Plating Catalyst

The substrate 70 with non-penetrating holes 11 formed thereon was immersed, for 5 minutes, in a commercial palladium chloride (PdCl₂) aqueous solution (Activator from Okuno Chemical Industries Co., Ltd.) that had been adjusted to be at 30° C. Thereafter, the substrate was removed from the palladium chloride aqueous solution, and was water-washed.

(b) Electroless Plating, and Electroplating

Next, the substrate was immersed, for 10 minutes, in an electroless nickel-phosphorus plating solution (Top Nicoron LPH-L from Okuno Chemical Industries Co., Ltd., at a pH of 6.5) that had been adjusted to be at 60° C. A nickel-phosphorus film (i.e., electroless nickel-phosphorus plating film) grew about 1 μm on the wiring region 10A.

On the nickel-phosphorus film were further deposited: a 95 μm copper electroplating film; a 4.0 μm electroless nickel-phosphorus plating film; and a 0.1 μm electroless gold film plating in this order, to form circuit wiring 20. The copper electroplating was performed by an electroplating method with high throwing power. The copper electroplating solution used was a mixture of liquid A: Top Lucina 2000 from Okuno Chemical Industries Co., Ltd.; and liquid B: Copper Gleam HS-200 from Rohm and Haas Electronic Materials LLC. This resulted in circuit wiring 20 composed of an electroless plating film and an electroplating film on the wiring region 10A illuminated with a laser beam.

(5) Mounting of Mounted Component

The mounted component 30 used was a surface-mounting-type high luminance LED (NS2W123BT from Nichia Corporation; 3.0 mm by 2.0 mm by 0.7 mm in height). First, as shown in FIG. 1, five mounted components 30 were placed on the circuit wiring 20 with solder at room temperature positioned therebetween. The distance between adjacent mounted components 30 was 0.5 mm. Next, the substrate with the LEDs placed thereon was loaded into a reflow furnace (solder reflow). The substrate was heated inside the reflow furnace, where the maximum temperature reached by the substrate was 240° C. to 260° C., with the substrate being heated at the maximum reached temperature for about 1 minute. The solder caused the mounted components 30 to be mounted on the resin 10, resulting in the circuit part 100 of the present inventive example shown in FIG. 1.

[Inventive Examples 2 to 12]

For each of Inventive Examples 2 to 12, a circuit part 100 was produced by the same method as for Inventive Example 1, except that the thickness of the insulating resin layer 10, the laser drawing conditions, the various dimensions in the laser-drawn pattern shown in FIG. 6 (N₁ to N₄), and the thickness of the circuit wiring (i.e., thickness of the plating film) were changed to the relevant values shown in Tables 1, 2 and 4. For Inventive Examples 5 to 12, the YVO₄ laser used for Inventive Example 1 was replaced with a UV laser (MD-U1000C three-dimensional laser marker from Keyence Corporation, with an output of 2.5 W).

Further, the width D and depth d of the penetrating holes 11 as well as the distance P for the non-penetrating holes 11 were calculated in the same manner as for Inventive Example 1. The calculated values of the width D and depth d of the penetrating holes 11 as well as the distance P for the non-penetrating holes 11 and the ratio d/D are shown in Tables 4 and 5.

### Inventive Example 13

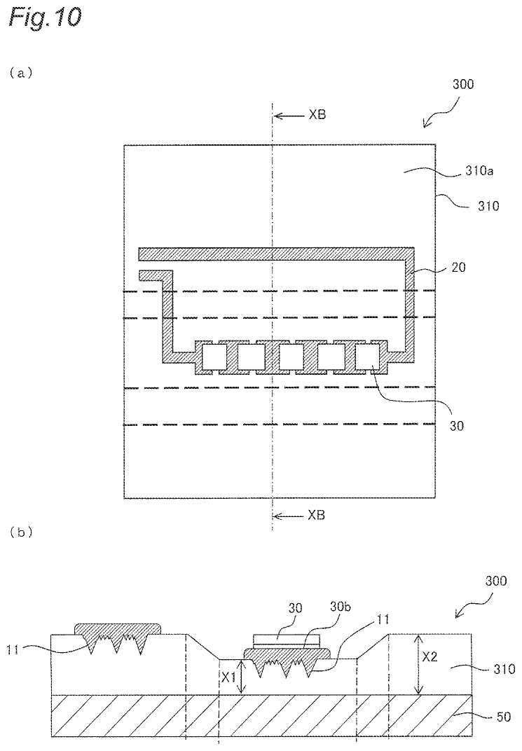

For the present inventive example, a circuit part 300 as shown in FIGS. 10(a), (b) was produced. In the circuit part 300, the thickness of the resin layer 310 was not constant, as shown in FIG. 10(b). Otherwise, the circuit part was substantially the same as the circuit part 100 shown in FIG. 1.

For the present inventive example, the smallest film thickness of the resin layer 310, X1, was 75 μm, and the largest film thickness X2 was 450 μm. Since the insulating resin 310 contained filler (i.e., alumina particles) with a maximum particle diameter of 35 μm, it was difficult to mold the entire insulating resin 310 with a thickness of 75 μm; providing a thickness of 75 μm only for some portions made the molding possible. Providing sub-regions with smaller film thicknesses (i.e., regions with the film thickness X1) improves the heat dissipation of the circuit part 300. Further, it is preferable that the sub-regions with smaller film thicknesses (i.e., regions with the film thickness X1) are located in areas where the mounted components (LED) 30, which are sources of heat, are mounted.

For the present inventive example, a circuit part 300 was produced by the same method as for Inventive Example 1 except that the thickness of the insulating resin layer 310, the laser drawing conditions, the various dimensions in the laser-drawn pattern shown in FIG. 6 (N₁ to N₄), and the thickness of the circuit wiring (i.e., thickness of the plating film) were changed to the relevant values shown in Tables 2 and 5. For the present inventive example, the UV laser used for Inventive Example 5 was used to form the non-penetrating holes 11.

Further, the width D and depth d of the penetrating holes 11 as well as the distance P for the non-penetrating holes 11 were calculated by the same method as for Inventive Example 1. The calculated values of the width D and depth d of the penetrating holes 11 as well as the distance P for the non-penetrating holes 11 and the ratio d/D are shown in Table 5.

### Inventive Example 14

For the present inventive example, a circuit part was produced having a resin layer 310 with non-constant thickness, as is the case with the circuit part 300 shown in FIGS. 10(a), (b), and including a ceramic layer 60, as is the case with the circuit part 200 shown in FIG. 9. The circuit part produced for the present inventive example was substantially the same as the circuit part 100 shown in FIG. 1 except that the thickness of the resin layer was not constant and it included a ceramic layer. For the present inventive example, the smallest film thickness X1 of the resin layer was 65 μm, and the largest film thickness X2 was 450 μm.

First, a metal member similar to the one used for Inventive Example 1 was prepared, on which degreasing and chemical etching was performed before hard alumite processing was performed (TAF-TR from Toadenka Co., Ltd.). This resulted in an anodic oxidation coating (i.e., alumite) over the entire metal member. The film thickness of the anodic oxidation coating was 50 μm.

Starting with the metal member with the anodic oxidation coating formed thereon the circuit part for the present inventive example was produced by the same method as for Inventive Example 1 except that the thickness of the insulating resin layer, the laser drawing conditions, the various dimensions in the laser-drawn pattern shown in FIG. 6 (N₁ to N₄), and the thickness of the circuit wiring (i.e., thickness of the plating film) were changed to the relevant values shown in Tables 2 and 5. For the present inventive example, the UV laser used for Inventive Example 5 was used to form non-penetrating holes.

Further, the width D and depth d of the penetrating holes 11 as well as the distance P for the non-penetrating holes 11 were calculated by the same method as for Inventive Example 1. The calculated values of the width D and depth d of the penetrating holes 11 as well as the distance P for the non-penetrating holes 11 and the ratio d/D are shown in Table 5.

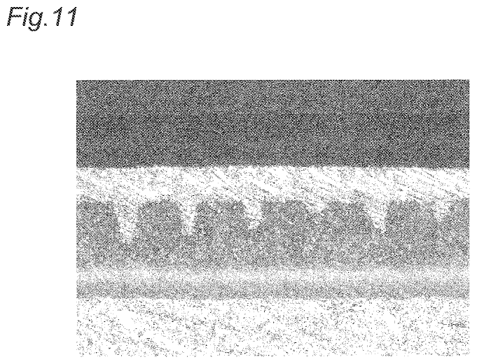

Further, a microscope (VH-6000 from Keyence Corporation) was used to perform cross-sectional observation of the circuit part of the present inventive example. As shown in FIG. 11, it was observed that the non-penetrating holes were regularly formed in the insulating resin layer.

### Comparative Example 1

For the present comparative example, the non-penetrating holes 11 were replaced with a grid pattern composed of grooves (i.e., recesses) on the entire wiring region 10A of the substrate 70.

(1) Preparation of Substrate

A substrate was produced having an insulating resin layer on a metal member by the same method as for Inventive Example 1 except that the thickness of the insulating resin layer was 150 μm.

(2) Formation of Grid Pattern

A grid pattern was formed by laser machining in a region of the surface of the insulating resin layer on which circuit wiring was to be formed (i.e., wiring region), under the laser drawing conditions shown in Table 3. The grid pattern was a grid pattern with a pitch of 200 μm. The depth of the grooves forming the grid pattern (i.e., maximum depth of the laser machined portions) was 130 μm.

(3) Formation of Circuit Wiring and Mounting of Mounted Component

On the substrate provided with the grid pattern, circuit wiring was formed by the same method as for Inventive Example 1, and a mounted component was mounted thereon. This resulted in the circuit part for the present comparative example. The electroplating was performed under the same conditions as for Inventive Example 2 (plating solution composition, current density, and time), which were adjusted such that the average thickness of the circuit wiring was generally equal to that of Inventive Example 2. In Table 5, the value of the average thickness of the circuit wiring is shown in parentheses.

### Comparative Examples 2 to 4

As is the case with Comparative Example 1, for each of Comparative Examples 2 to 4, the non-penetrating holes 11 were replaced with a grid pattern composed of grooves (i.e., recesses) over the entire wiring region of the substrate. For Comparative Examples 2 to 4, a circuit part was produced by the same method as for Comparative Example 1 except that the thickness of the insulating resin layer 10, the laser drawing conditions and the average thickness of the circuit wiring were changed to the relevant values shown in Tables 3 and 5. For Comparative Examples 3 and 4, the YVO₄ laser used for Comparative Example 1 was replaced by a UV laser (MD-U1000C three-dimensional laser marker from Keyence Corporation, with an output of 2.5 W), and a grid pattern with a pitch of 80 μm was laser drawn.

### Comparative Example 5

As is the case with Comparative Example 1, for the present comparative example, the non-penetrating holes 11 were replaced with a grid pattern composed of grooves (i.e., recesses) over the entire wiring region of the substrate. However, for the present comparative example, a circuit part was produced having a resin layer 310 with non-constant thickness, as is the case with the circuit part 300 shown in FIGS. 10(a), (b), and including a ceramic layer 60, as is the case with the circuit part 200 shown in FIG. 9. The circuit part produced for the present comparative example was the same as the circuit part produced for Comparative Example 1 except that the thickness of the resin layer was not constant and it included a ceramic layer. For the present comparative example, the smallest film thickness X1 of the resin layer was 65 μm, and the largest film thickness X2 was 450 μm.

First, a metal member similar to the one used for Comparative Example 1 was prepared, on which degreasing and chemical etching was performed before hard alumite processing was performed (TAF-TR from Toadenka Co., Ltd.). This resulted in an anodic oxidation coating (i.e., alumite) over the entire metal member. The film thickness of the anodic oxidation coating was 50 μm.

Starting with the metal member with the anodic oxidation coating formed thereon, the circuit part for the present comparative example was produced by the same method as for Comparative Example 1 except that the thickness of the insulating resin layer, the laser drawing conditions, and the average thickness of the circuit wiring were changed to the relevant values shown in Tables 3 and 5. For the present comparative example, the YVO₄ laser used for Comparative Example 1 was replaced with the UV laser used for Comparative Example 3.

[Comparative Examples 6 and 7]

For Comparative Examples 6 and 7, a plurality of through-holes 11 were formed in the region of the surface 10a of the insulating resin layer 10 on which the circuit wiring 20 was to be formed (i.e., wiring region 10A). For Comparative Examples 6 and 7, a circuit part 100 was produced by the same method as for Inventive Example 1 except that the thickness of the insulating resin layer 10, the laser drawing conditions, the various dimensions in the laser-drawn pattern shown in FIG. 6 (N₁ to N₄), and the thickness of the circuit wiring (i.e., thickness of the plating film) were changed to the relevant values shown in Tables 3 and 5. For Comparative Examples 6 and 7, the YVO₄ laser used for Inventive Example 1 was replaced with the UV laser used for Comparative Example 3.

Further, the width D and depth d of the penetrating holes 11 as well as the distance P for the non-penetrating holes 11 were calculated by the same method as for Inventive Example 1. The calculated values of the width D and depth d of the penetrating holes 11, the distance P for the non-penetrating holes 11 and the ratio d/D are shown in Table 5. It is to be noted that the depth d of the non-penetrating holes 11 of Comparative Example 7 was determined by cross-sectional observation.

TABLE 1

| | | Inventive Examples | | | | | | | |
|---|---|---|---|---|---|---|---|---|---|
| | | 1 | 2 | 3 | 4 | 5 | 6 | 7 | 8 |
| Ceramic Layer | | — | — | — | — | — | — | — | — |
| Thickness | | 200 | 150 | 150 | 150 | 200 | 100 | 100 | 100 |
| of Resin Layer (μm) | | | | | | | | | |
| Laser | Laser type | YVO₄ | YVO₄ | YVO₄ | YVO₄ | UV | UV | UV | UV |
| Drawing | Power (%) | 80 | 80 | 80 | 80 | 80 | 80 | 80 | 80 |
| Conditions | Linear | 30 | 100 | 400 | 800 | 20 | 200 | 200 | 100 |
| | velocity | | | | | | | | |
| | (mm/s) | | | | | | | | |
| | Frequency | 50 | 50 | 50 | 50 | 50 | 100 | 100 | 100 |
| | (kHz) | | | | | | | | |
| | No. of | 1 | 1 | 1 | 1 | 3 | 1 | 1 | 1 |
| | rounds | | | | | | | | |
| | of drawing | | | | | | | | |
| Laser | N1 (μm) | 35 | 35 | 35 | 35 | 10 | 10 | 10 | 10 |
| Drawing | N2 (μm) | 365 | 215 | 215 | 215 | 90 | 90 | 90 | 90 |
| Pattern | N3 (μm) | 200 | 160 | 200 | 200 | 80 | 80 | 80 | 80 |
| Size | N4 (μm) | 200 | 125 | 125 | 125 | 50 | 50 | 50 | 50 |

TABLE 2

| | | Inventive Examples | | | | | |
|---|---|---|---|---|---|---|---|
| | | 9 | 10 | 11 | 12 | 13 | 14 |
| Ceramic Layer | | — | — | — | — | — | alumite |
| Thickness | | 150 | 100 | 100 | 100 | 75-450 | 65-450 |
| of Resin Layer (μm) | | | | | | | |
| Laser | Laser type | UV | UV | UV | UV | UV | UV |
| Drawing | Power (%) | 80 | 80 | 80 | 80 | 80 | 80 |
| Conditions | Linear | 20 | 20 | 20 | 20 | 20 | 20 |
| | velocity | | | | | | |
| | (mm/s) | | | | | | |
| | Frequency | 100 | 100 | 100 | 100 | 100 | 100 |
| | (kHz) | | | | | | |
| | No. of | 1 | 1 | 1 | 1 | 1 | 1 |
| | rounds | | | | | | |
| | of drawing | | | | | | |
| Laser | N1 (μm) | 10 | 10 | 10 | 10 | 10 | 10 |
| Drawing | N2 (μm) | 90 | 70 | 110 | 190 | 90 | 90 |
| Pattern | N3 (μm) | 80 | 60 | 100 | 120 | 80 | 80 |
| Size | N4 (μm) | 50 | 40 | 60 | 100 | 50 | 50 |

TABLE 3

| | | Comparative Examples | | | | | | |
|---|---|---|---|---|---|---|---|---|
| | | 1 | 2 | 3 | 4 | 5 | 6 | 7 |
| Ceramic Layer | | — | — | — | — | alumite | — | — |
| Thickness | | 150 | 150 | 100 | 100 | 65-450 | 100 | 420 |
| of Resin Layer (μm) | | | | | | | | |
| Laser | Laser type | YVO₄ | YVO₄ | UV | UV | UV | UV | UV |
| Drawing | Power (%) | 80 | 80 | 80 | 80 | 80 | 80 | 80 |
| Conditions | Linear | 800 | 1600 | 200 | 600 | 600 | 200 | 20 |
| | velocity | | | | | | | |
| | (mm/s) | | | | | | | |
| | Frequency | 50 | 50 | 100 | 100 | 100 | 100 | 50 |
| | (kHz) | | | | | | | |
| | No. of | 1 | 1 | 1 | 1 | 1 | 1 | 10 |
| | rounds | | | | | | | |
| | of drawing | | | | | | | |
| Laser | N1 (μm) | — | — | — | — | — | 10 | 10 |
| Drawing | N2 (μm) | — | — | — | — | — | 90 | 90 |
| Pattern | N3 (μm) | — | — | — | — | — | 80 | 80 |
| Size | N4 (μm) | — | — | — | — | — | 50 | 50 |

[Evaluation of Circuit Part]

The above-described circuit parts fabricated for Inventive Examples 1 to 14 and Comparative Examples 1 to 7 were evaluated as described further below. The evaluation results are shown in Tables 4 and 5. Further, together with the evaluation results, the following values relating to the circuit parts for Inventive Examples 1 to 14 and Comparative Examples 1 to 7 are shown in Tables 4 and 5: the width D and depth d of the non-penetrating holes 11; the ratio d/D; the distance P for the non-penetrating holes 11; the ratio P/D; the surface roughness of the wiring region 10A (Ra); the ratio d/5; the thickness B of the resin layer below the circuit wiring; the distance C; the thickness A of the circuit wiring; and the smaller one of the values of D/2 and d/2. Further, for Comparative Examples 1 to 5, the depth d of the non-penetrating holes 11 and the thickness A of the circuit wiring are replaced with the depth of the grooves forming the grid pattern and the average thickness of the circuit wiring, shown in parentheses in Table 5.

(1) Adhesion Testing of Circuit Wiring (Plating Film)

Separately from the above-described circuit parts fabricated for Inventive Examples 1 to 14 and Comparative Examples 1 to 7, specimens for adhesion testing for the inventive and comparative examples were prepared by the following method: First, substrates were prepared composed of metal members and insulating resin layers of the same respective materials that were used for Inventive Examples 1 to 14 and Comparative Example 1 to 7. Laser drawing was performed on the insulating resin layers of the substrates in the same respective manner as for the inventive and comparative examples. On each substrate after laser drawing was formed a 1 μm electroless nickel-phosphorus plating film, on top of which a 40 μm copper electroplating was formed to produce a specimen for adhesion testing. The plating film of each specimen had a size of 2 mm in width and 40 mm in length. The adhesive strength of the plating film of the measurement specimen was measured by perpendicular tensile testing, and the adhesion of the circuit wiring (i.e., plating film) was evaluated in accordance with the following evaluation criteria.

<Evaluation Criteria for Adhesion>

A: The adhesive strength of the plating film of a measurement specimen was not lower than 15 N/cm.

B: The adhesive strength of the plating film of a measurement specimen was not lower than 10 N/cm and lower than 15 N/cm.

C: The adhesive strength of the plating film of a measurement specimen was not lower than 1 N/cm and lower than 3 N/cm.

E: The adhesive strength of the plating film of a measurement specimen was lower than 1 N/cm.

(2) Insulation Testing of Insulating Resin Layer

In each of the circuit parts fabricated for Inventive Examples 1 to 14 and Comparative Examples 1 to 7, a voltage of 500 V was applied between the circuit wiring 20 and metal member 50; the resistance value between the circuit wiring 20 and metal member 50 was measured using a tester; and the insulation of the insulating resin layer was evaluated based on the following evaluation criteria for insulation. It is to be noted that for Inventive Example 14 and Comparative Example 5, portions of the alumite layer on which no insulating resin layer was formed were ground with a metal file to expose the metal member, and the resistance between the circuit wiring 20 and metal member 50 was measured.

<Evaluation Criteria for Insulation>

A: The resistance value between the circuit wiring 20 and metal member 50 was not lower than 5000 MΩ.

B: The resistance value between the circuit wiring 20 and metal member 50 was not lower than 100 MΩ and lower than 5000 MΩ.

C: The resistance value between the circuit wiring 20 and metal member 50 was not higher than 1 MΩ.

E: A short circuit was found between the circuit wiring 20 and metal member 50.

(3) Heat Dissipation Testing of Circuit Part

In each of the circuit parts fabricated for Inventive Examples 1 to 14 and Comparative Examples 1 to 7, a thermocouple was bonded to an end of the mounted component (i.e., LED) 30; a constant current (0.8 A) was caused to flow therethrough to turn on the LED 30; and, 30 minutes after the LED 30 had been turned on, the temperature thereof was measured. The average temperature of all the LEDs 30 on the circuit part was calculated and the heat dissipation of the circuit part was evaluated in accordance with the evaluation criteria provided below. However, for the circuit part in which a short circuit between the circuit wiring 20 and metal member 50 was found during the above-described “(2) Insulation Testing” of the insulating resin layer (evaluation result: E), the present testing was not conducted since current would have flowed through the metal member, making it impossible to measure a correct value.

<Evaluation Criteria for Heat Dissipation of Circuit Part>

A: The LED surface temperature 30 minutes after it had been turned on was not higher than 90° C.

B: The LED surface temperature 30 minutes after it had been turned on was higher than 90° C. and not higher than 100° C.

C: The LED surface temperature 30 minutes after it had been turned on was higher than 100° C. and not higher than 120° C.

E: The LED surface temperatures 30 minutes after it had been turned on was higher than 120° C.

(4) Evaluation of Flatness of Circuit Wiring (Plating Film)

For each of the circuit parts fabricated for Inventive Examples 1 to 14 and Comparative Examples 1 to 7, the plating surface of the circuit wiring 20 was observed using a microscope, and the difference between the heights of the highest and deepest points of the plating surface was measured in a sectional profile (i.e., height profile) along the width direction of the circuit wiring. Such a measurement was performed for three fields of view and the average was treated as the surface roughness of the circuit wiring, and the flatness was evaluated based on the following evaluation criteria for flatness.

<Evaluation Criteria for Flatness>

A: The surface roughness of the circuit wiring was not greater than 5 μm.

B: The surface roughness of the circuit wiring was greater than 5 μm and not greater than 10 μm.

C: The surface roughness of the circuit wiring was greater than 10 μm and not greater than 20 μm.

E: The surface roughness of the circuit wiring was greater than 20 μm.

TABLE 4

| | | Inventive Examples | | | | | | | | | | | |
|---|---|---|---|---|---|---|---|---|---|---|---|---|---|
| | | 1 | 2 | 3 | 4 | 5 | 6 | 7 | 8 | 9 | 10 | 11 | 12 |
| Insulating | Width D | 155 | 152 | 110 | 102 | 54 | 39 | 40 | 38 | 41 | 42 | 40 | 41 |
| Resin | of non-penetrating holes (μm) | | | | | | | | | | | | |
| Layer | Depth d | 178 | 132 | 98 | 75 | 115 | 61 | 41 | 24 | 61 | 60 | 61 | 63 |
| | of non-penetrating holes (μm) | | | | | | | | | | | | |
| | Ratio d/D | 1.15 | 0.87 | 0.89 | 0.74 | 2.13 | 1.56 | 1.03 | 0.63 | 1.49 | 1.43 | 1.53 | 1.54 |
| | Distance P | 128 | 51 | 126 | 134 | 40 | 55 | 54 | 56 | 53 | 30 | 77 | 115 |
| | for non-penetrating holes | | | | | | | | | | | | |
| | (μm) | | | | | | | | | | | | |
| | Ratio P/D | 0.82 | 0.34 | 1.14 | 1.31 | 0.75 | 1.42 | 1.36 | 1.48 | 1.30 | 0.72 | 1.92 | 2.81 |
| | Surface roughness (Ra) | 13 | 12 | 14 | 12 | 4 | 4 | 5 | 4 | 4 | 4 | 4 | 4 |
| | of wiring region 10A | | | | | | | | | | | | |
| | (d/5) | 35.6 | 26.4 | 19.6 | 15 | 23 | 12 | 8 | 5 | 12 | 12 | 12 | 13 |
| | Thickness B of resin layer | 194 | 145 | 143 | 144 | 197 | 96 | 97 | 98 | 146 | 98 | 97 | 98 |
| | below circuit wiring (μm) | | | | | | | | | | | | |
| | Distance C (μm) | 16 | 13 | 45 | 69 | 82 | 35 | 56 | 74 | 85 | 38 | 36 | 35 |
| Circuit | Thickness A | 100 | 80 | 80 | 80 | 50 | 50 | 50 | 50 | 50 | 50 | 50 | 50 |
| Wiring | of circuit wiring (μm) | | | | | | | | | | | | |
| | Smaller one | 77.5 | 66 | 49 | 38 | 27 | 19.5 | 20 | 12 | 20.5 | 21 | 20 | 20.5 |
| | of D/2 and d/2 (μm) | | | | | | | | | | | | |
| Evaluation | (1) Adhesion | A | A | A | B | A | A | A | B | A | A | A | A |
| Results | (2) Insulation | B | B | A | A | A | A | A | A | A | A | A | A |
| | (3) Heat dissipation | B | B | B | B | B | A | B | B | B | A | A | A |
| | (4) Flatness | C | C | B | C | B | A | A | B | A | B | B | B |

TABLE 5

| | | Inventive Ex. | | Comparative Examples | | | | | | |
|---|---|---|---|---|---|---|---|---|---|---|
| | | 13 | 14 | 1 | 2 | 3 | 4 | 5 | 6 | 7 |
| Insulating | Width D | 40 | 40 | — | — | — | — | — | 40 | 68 |
| Resin | of non-penetrating holes (μm) | | | | | | | | | |
| Layer | Depth d | 62 | 58 | (130) | (90) | (80) | (52) | (51) | 15 | (352) |
| | of non-penetrating holes (μm) | | | | | | | | | |
| | Ratio d/D | 1.55 | 1.45 | — | — | — | — | — | 0.38 | 5.18 |
| | Distance P | 54 | 54 | — | — | — | — | — | 54 | 26 |
| | for non-penetrating holes | | | | | | | | | |
| | (μm) | | | | | | | | | |
| | Ratio P/D | 1.36 | 1.36 | — | — | — | — | — | 1.36 | 0.39 |
| | Surface roughness(Ra) | 5 | 4 | — | — | — | — | — | 3 | 5 |
| | of wiring region 10A | | | | | | | | | |
| | (d/5) | 12 | 12 | — | — | — | — | — | 3 | 70 |
| | Thickness B of resin layer | 73 | 62 | — | — | — | — | — | 97 | 445 |
| | below circuit wiring (μm) | | | | | | | | | |
| | Distance C (μm) | 11 | 4 | 20 | 60 | 20 | 48 | 14 | 82 | 93 |
| Circuit | Thickness A | 50 | 50 | (80) | (80) | (80) | (50) | (50) | 50 | 50 |
| Wiring | of circuit wiring (μm) | | | | | | | | | |
| | Smaller one | 20 | 20 | — | — | — | — | — | 8 | 34 |
| | of D/2 and d/2 (μm) | | | | | | | | | |
| Evaluation | (1) Adhesion | A | A | B | C | B | C | C | E | B |
| Results | (2) Insulation | B | A | E | C | E | C | E | A | E |
| | (3) Heat dissipation | A | A | — | E | — | E | — | E | — |
| | (4) Flatness | A | B | E | E | E | E | E | A | C |

As shown in Tables 4 and 5, it was found that, for each of the circuit parts fabricated for Inventive Examples 1 to 14, all the evaluation results were good: both high heat dissipation and high adhesion of circuit wiring were achieved, the circuit wiring and metal member were reliably insulated, and the surface of the circuit wiring was flat. Also, for each of the circuit parts of Inventive Examples 1 to 14, the surface roughness (Ra) of the wiring region 10A was not greater than ⅕ of the depth d of the non-penetrating holes 11, the ratio P/D was in the range of 0.3 to 3, the thickness A of the circuit wiring (i.e., plating film) 20 was either larger than ½ of the depth d of the non-penetrating holes 11 or larger than ½ of the width D, the width D of the non-penetrating holes was in the range of 10 to 200 μm, the thickness B of the resin layer was in the range of 30 to 200 μm, and the distance C was in the range of 5 to 100 μm.

On the other hand, for each of Comparative Examples 1 to 5 which replaced the non-penetrating holes 11 with a grid pattern composed of grooves (i.e., recesses) over the entire wiring region 10A, the result of the evaluation of flatness was poor (evaluation result: E). This is presumably because the recesses and protrusions of the grid pattern formed over the entire wiring region 10A deteriorated the flatness of the plating film formed thereupon.

Further, for each of Comparative Examples 1, 3 and 5, in addition to the result of the evaluation of flatness, the result of the evaluation of insulation was poor (evaluation result: E); accordingly, no heat dissipation test was conducted. The reason for these results is presumed to be the following: If grooves are formed in a grid by laser drawing, the intersections are illuminated twice with a laser beam, which increases variations in groove depth. The microscopic observations allowed only grooves with depths smaller than the thickness of the insulating resin layer to be observed. However, in the real grid pattern, there were portions with grooves of depths larger than the thickness of the insulating resin layer, which is presumed to have decreased insulation.

Further, for each of Comparative Examples 2 and 4, in addition to the result of the evaluation of flatness, the result of the evaluation of heat dissipation was poor (evaluation result: E). The reason for this result is presumed to be the following: A first presumed factor is that the decreased smoothness of the plating film increased the film thickness of solder between the plating film and mounted component. A second factor is that Comparative Examples 2 and 4, compared with Comparative Examples 1 and 3, respectively, had improved insulation due to the smaller groove depths, but had decreased adhesion between the plating film and insulating resin layer (evaluation result: C). This is presumed to have increased the heat resistance from the plating film to the insulating resin layer. A presumed third factor is that the smaller groove depths increased the thicknesses of portions of the insulating resin layer between the plating film and metal member (i.e., distance C), leading to decreased heat transfer to the metal member.

Further, for Comparative Example 6 where the ratio d/D of the non-penetrating holes 11 was lower than 0.5, the results of the evaluations of adhesion and heat dissipation were poor (evaluation result: E). For Comparative Example 6, the same factors as the above-discussed second and third factors for the decreased heat dissipation for Comparative Examples 2 and 4 are presumed to have decreased the adhesion between the plating film and insulating resin layer and increased the thickness of portions of the insulating resin layer between the plating film and metal member (i.e., distance C), decreasing heat dissipation.

For Comparative Example 7 where the ratio d/D of the non-penetrating holes 11 was not lower than 5, the result of the evaluation of insulation was poor (evaluation result: E); accordingly, no heat dissipation test was conducted. The reason for this result is presumed to be the following: For Comparative Example 7, the number of rounds of laser drawing was increased (number of rounds of laser drawing: 10) to increase the depth of the non-penetrating holes 11. A cross-sectional observation showed that the thickness of portions of the insulating resin layer between the bottoms of the non-penetrating holes 11 and metal member (i.e., distance C) was 93 μm; however, the larger number of rounds of laser drawing is presumed to have rendered portions of the insulating resin layer between the non-penetrating holes 11 and metal member brittle. It is presumed that the brittle insulating resin layer was penetrated by plating solution such that plating film grew, which caused a short circuit between the circuit wiring (i.e., plating film) and metal member.

### INDUSTRIAL APPLICABILITY

The circuit part of the present invention has high heat dissipation. Thus, the circuit part of the present invention is suitably used as a part with a mounted component such as an LED mounted thereon, and is applicable as a part in a smartphone or an automobile.

### REFERENCE SIGNS LIST

10: insulating resin layer
11: non-penetrating holes (recesses)
20: circuit wiring
30: mounted component (LED)
50: metal member
70: substrate
100: circuit part

1. A circuit part comprising:
a metal member;
an insulating resin layer located on the metal member;
circuit wiring including a plating film located on the insulating resin layer; and
a mounted component mounted on the circuit wiring and electrically connected to the circuit wiring,
wherein a plurality of non-penetrating holes are provided in a wiring region, the non-penetrating holes being filled with the plating film, the wiring region being a portion of a surface of the insulating resin layer on which the circuit wiring is located,
a ratio of a depth d of the non-penetrating holes to a width D of the non-penetrating holes, d/D, is 0.5 to 5, and
a ratio of a distance P between adjacent ones of the non-penetrating holes to the width D of the non-penetrating holes, P/D, is 0.3 to 3.

2. The circuit part according to claim 1, wherein a surface roughness of a portion of the wiring region other than portions of the non-penetrating holes, Ra, is not greater than ⅕ of the depth d of the non-penetrating holes.

3. (canceled)

4. The circuit part according to claim 1, wherein a thickness of the circuit wiring is larger than ½ of the depth d of the non-penetrating holes or larger than ½ of the width D.

5. The circuit part according to claim 1, wherein the width D of the non-penetrating holes is 10 to 200 μm.

6. The circuit part according to claim 1, wherein a thickness of a portion of the insulating resin layer sandwiched between the circuit wiring and the metal member and which does not include the non-penetrating holes is 30 to 200 μm.

7. The circuit part according to claim 1, wherein a distance between bottoms of the non-penetrating holes and a face of the insulating resin layer facing the metal member is 5 to 100 μm.

8. The circuit part according to claim 1, wherein the non-penetrating holes are disposed in such a sporadic manner that a density of the non-penetrating holes in the wiring region is generally uniform.

9. The circuit part according to claim 1, wherein the insulating resin layer includes a thermosetting resin.

10. The circuit part according to claim 9, wherein the thermosetting resin is epoxy resin.

11. The circuit part according to claim 1, wherein the insulating resin layer includes an insulating thermal-conductive filler.

12. The circuit part according to claim 1, further comprising: an inorganic oxide layer between the metal member and the insulating resin layer.

13. The circuit part according to claim 1, wherein the mounted component is positioned such that a surface thereof provided with a terminal faces the circuit wiring, and the terminal and the circuit wiring are electrically connected by solder.

14. A method of manufacturing the circuit part according to claim 1, comprising:
preparing the metal member;
forming the insulating resin layer on the metal member;
forming the plurality of non-penetrating holes by illuminating the wiring region of the insulating resin layer with a laser beam;
forming the circuit wiring in the wiring region by electroplating; and
mounting the mounted component on the circuit wiring.
